(19) United States
(12) Patent Application Publication
(10) Pub. No.: US 2014/0159129 A1
(43) Pub. Date: Jun. 12, 2014

(54) NEAR-INFRARED-VISIBLE LIGHT ADJUSTABLE IMAGE SENSOR

(71) Applicant: Fudan University, Shanghai (CN)

(72) Inventors: Pengfei Wang, Shanghai (CN); Xinyan Liu, Shanghai (CN); Qingqing Sun, Shanghai (CN); Wei Zhang, Shanghai (CN)

(21) Appl. No.: 13/920,696

(22) Filed: Jun. 18, 2013

(30) Foreign Application Priority Data
Dec. 10, 2012 (CN) 201210529104.2

(51) Int. Cl. H01L 27/146

(52) U.S. Cl. CPC H01L 27/14643; H01L 27/14689
USPC 257/292; 438/59

(57) ABSTRACT

The disclosure belongs to the field of semiconductor photoreceptors, in particular to a near-infrared-visible light adjustable image sensor. By adding a transfer transistor, the disclosure integrates a silicon-based photoelectric diode and a silicon germanium-based photoelectric diode on the same chip to realize that the silicon-based photoelectric diode and a silicon germanium-based photoelectric diode are controlled by the same readout circuit at different time, thus widening the spectrum response scope of the photoreceptor, realizing high integration and multifunction of the chip and reducing the manufacturing cost of the chip. The disclosure is applicable for intermediate and high-end products with low power consumption and photoreceptors for specific wave bands, in particular to military, communicative and other special fields.

### CROSS-REFERENCE TO RELATED APPLICATION

This application claims the benefit of and priority to Chinese patent application No. 201210529104.2 filed on Dec. 10, 2012, the entire content of which is incorporated by reference herein.

### BACKGROUND

1. Technical Field

The present disclosure relates to an image sensor, in particular to a near-infrared-visible light adjustable image sensor and a manufacturing method thereof, belonging to the field of semiconductor photoreceptors.

2. Description of Related Art

A complementary metal-oxide-semiconductor (CMOS) image sensor comprises a plurality of MOS transistors and a signal processing circuit portion used as a peripheral circuit, and is integrated on a semiconductor substrate by COMS technology. The core sensor part-single pixel of the traditional COMS image sensor mainly comprises a reverse bias diode and an amplified MOS transistor. The output of each unit pixel is detected by the MOS transistor in turn. FIG. 1 illustrates a circuit structure of a single pixel unit of an existing COMS image sensor. As shown in FIG. 1, a single pixel unit of this COMS image sensor has four MOS transistor and specifically comprises a photoelectric diode (PD) 1, a charge overflow gate tube (TG) 2, a reset transistor (RST) 3, a source follower (SF) 4, a selector transistor (RS) 5 and a capacitor (FD) 6. Its working process as follows: firstly, enter the “resetting state”; in which the reset transistor is switched on to reset the photoelectric diode; then, enter the “sampling state”, in which the reset transistor is switched off, and photon-generated carriers are generated when light irradiates on the photoelectric diode, amplified and output through the source follower; and finally, enter the “readout state”, in which the selector transistor is switched on; signals are output via a bus (Vout); and Vdd is the power supply voltage.

The traditional photoelectric diode includes the silicon-based photoelectric diode and the silicon germanium-based photoelectric diode. The structure of the traditional silicon-based photoelectric diode can be seen in FIG. 2, which comprises an n-type heavily doped region 10, an n-type lightly doped region 11 and a p-type heavily doped region 13 which are formed in a silicon substrate; a depletion region 12 is formed between the n-type lightly doped region 11 and the p-type heavily doped region 13; and an oxide layer 14 and a metal electrode 15 are also formed on the silicon substrate. The structure of the traditional silicon germanium-based photoelectric diode can be seen in FIG. 3, which comprises: a heavily doped p-type silicon substrate 20, a heavily doped p-type germanium substrate 21 formed the p-type silicon substrate 20, an intrinsic germanium substrate 22 formed on the p-type germanium substrate 21, and an n-type heavily doped region 23 formed in the intrinsic germanium substrate 22, and also comprises an aluminum oxide media layer 24, an oxide layer 25 and a metal electrode 26.

The visible light image sensor consisting of the silicon-based photoelectric diodes particularly emphasizes on the signal size, while the near-infrared sensor consisting of the silicon germanium-based photoelectric diodes particularly emphasizes on existence of the signals. The two are respectively used in the civil and military fields. At present, the silicon-based image sensor and the silicon germanium-based image sensor are integrated in different chips which only have single function and are of low integration.

### SUMMARY

Thereby, the objective of the disclosure is to provide a near-infrared-visible light adjustable image sensor, in which the silicon-based image sensor and the silicon germanium-based image sensor are integrated on the same chip to increase the integration degree and function of the chip.

To fulfill the above objective, the disclosure provides a near-infrared-visible light adjustable image sensor, which comprises:

a p-type doped silicon substrate;

a silicon-based photoelectric diode formed on side silicon substrate;

a silicon germanium-based photoelectric diode formed on side silicon substrate;

a first transistor and a second transistor formed in said silicon substrate and between said silicon-based photoelectric diode and said silicon germanium-based photoelectric diode;

and a conductive floating node formed on said silicon substrate and between said first and second transistors and serving as a charge storage node.

For the near-infrared-visible light adjustable image sensor, the source region of said first transistor is connected with the n-type doping region of said silicon-based photoelectric diode. The source region of said second transistor is connected with the n-type doped region of said silicon germanium-based photoelectric diode. Said first and second transistors share the same drain region, and said region is connected with said floating node.

Furthermore, the disclosure also provides a manufacturing method for the near-infrared-visible light adjustable image sensor, which comprises:

etch the provided p-type doped silicon substrate to form a region for forming a silicon germanium-based photoelectric diode;

growing a layer of silicon germanium on the epitaxy in the region for forming said silicon germanium-based photoelectric diode;

respectively forming a first n-type doped region and a second n-type doped region in the said silicon substrate and the epitaxial layer of the formed silicon germanium;

respectively forming a first n-type source region, a second n-type source region and an n-type region which all are heavily doped in said first n-type doped region, said second n-type doped region and said silicon substrate between said first and second n-type doped regions;

forming a gate oxide layer on the surface of the formed structure;

Etching said gate oxide layer to expose said n-type drain region;

forming conductive layers on said gate oxide layer between said first n-type source region and said n-type drain region and on the gate oxide layer between said second n-type source region and said n-type drain region, and forming a conductive floating node serving as a charge storage node on the surface of said exposed n-type region.

The disclosure integrates a silicon-based photoelectric diode and a silicon germanium-based photoelectric diode on the same chip and adds a transfer transistor to realize that the silicon-based photoelectric diode and a silicon germanium-based photoelectric diode are controlled by the same readout circuit at different times, thus widening the spectrum response scope of the photoreceptor, realizing high integration and multifunction of the chip and reducing the manufacturing cost of the chip. The disclosure is applicable for intermediate and high-end products with low power consumption and photoreceptors for specific wave bands, in particular to military, communicative and other special fields.

### BRIEF DESCRIPTION OF THE DRAWINGS

FIG. 1 illustrates a circuit structure of a single pixel unit of an existing COMS image sensor.

FIG. 2 is a sectional view of the structure of a traditional silicon-based photoelectric diode

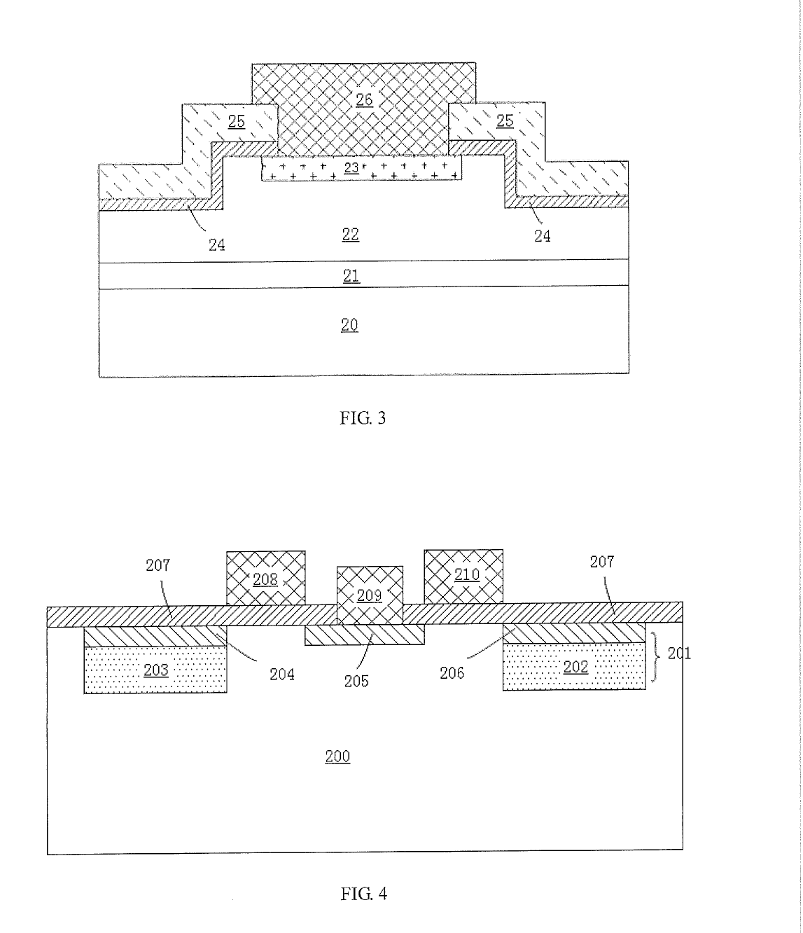

FIG. 3 is a sectional view of the structure of a traditional silicon germanium-based photoelectric diode

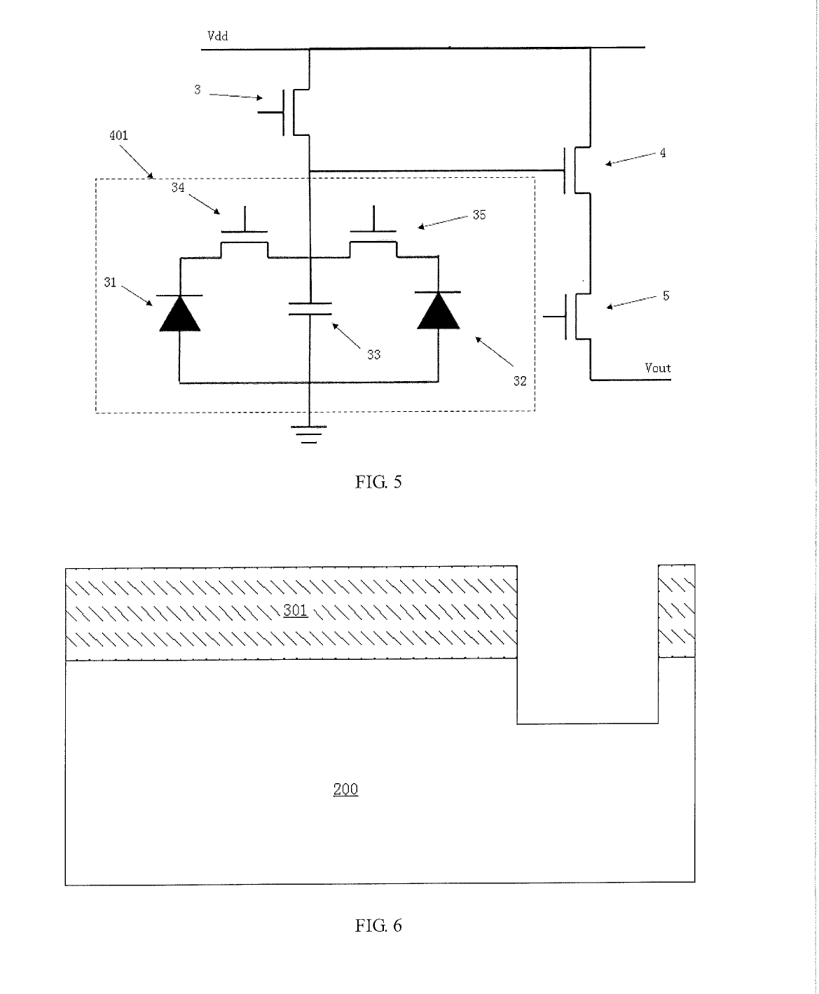

FIG. 4 is a sectional view of an embodiment of a near-infrared-visible light adjustable image sensor disclosed in the disclosure.

FIG. 5 illustrates an embodiment of a circuit diagram of a single pixel unit of a CMOS image sensor formed by the near-infrared-visible light adjustable image sensor disclosed in the disclosure.

FIGS. 6-12 are process flowcharts of an embodiment of a manufacturing method for the near-infrared-visible light adjustable image sensor disclosed in the disclosure.

### DETAILED DESCRIPTION

The disclosure is further described in detail with reference to the attached drawings and the embodiment. In the figures, for convenience, the thicknesses of the layers and regions are amplified or reduced, and said dimensions do not represent the actual dimensions. The figures cannot completely and accurately reflect the actual dimensions of the devices, but they still completely reflect the mutual positions of the regions and the structures, in particular the vertical and neighbor relations between the structures.

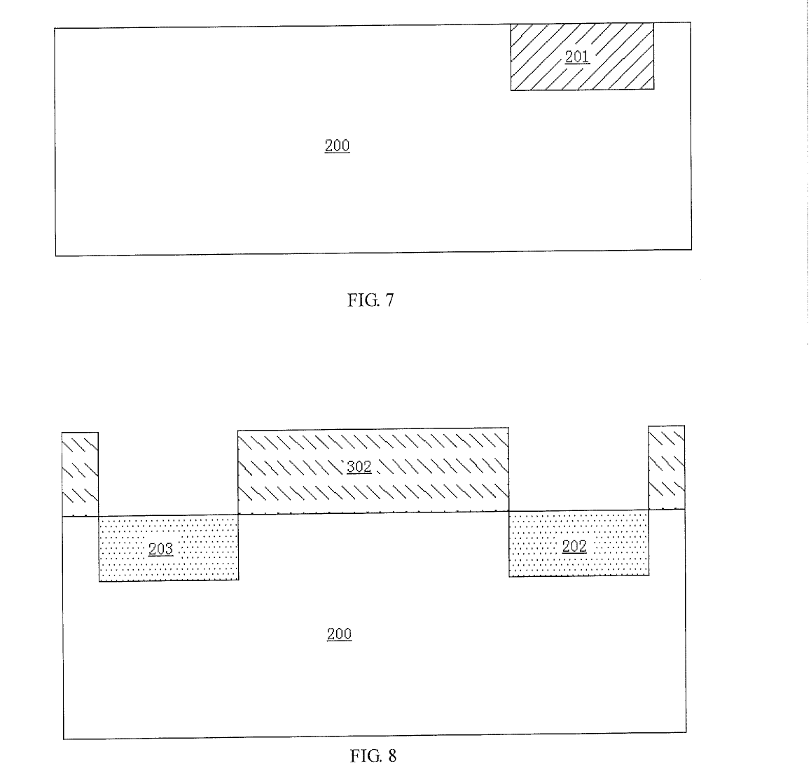

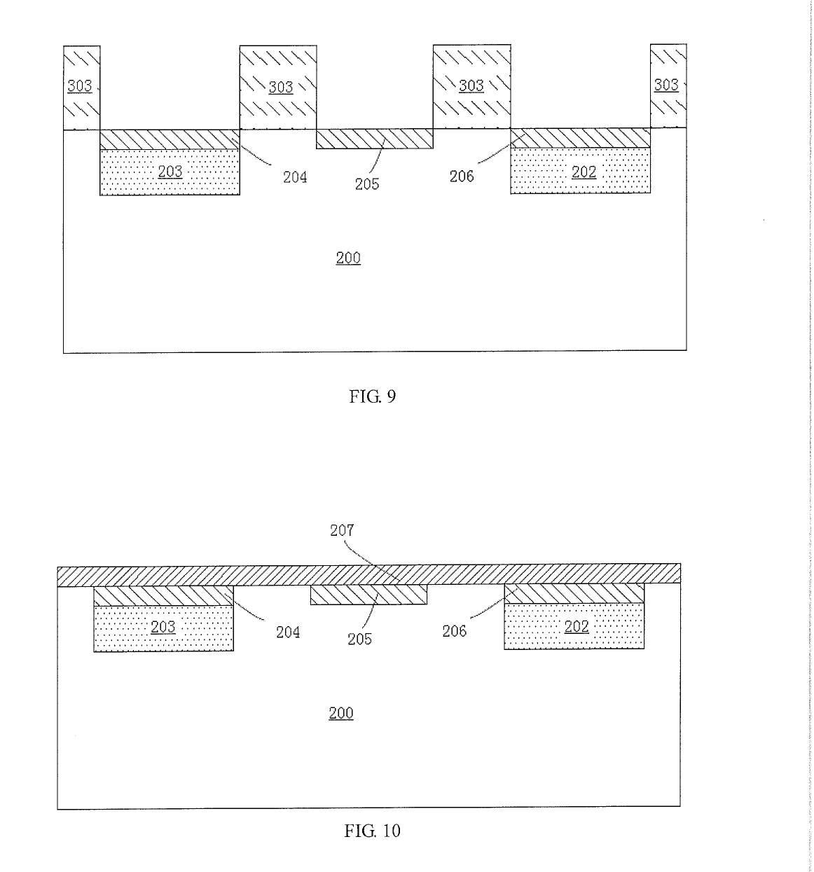

FIG. 4 is a sectional view of an embodiment of the near-infrared-visible light adjustable image sensor disclosed in the disclosure. FIG. 5 is an embodiment of a circuit diagram of a single pixel unit of a CMOS image sensor consisting of the near-infrared-visible light adjustable image sensor disclosed in the disclosure. As shown in FIGS. 4 and 5, the near-infrared-visible light adjustable image sensor disclosed in the disclosure comprises a p-type doped silicon substrate 200, a silicon germanium epitaxial layer 201 formed in the silicon substrate 200, a first n-type doped region 203 and a second n-type doped region 202 respectively formed in the silicon substrate 200 and the silicon germanium epitaxial layer 201. The first n-type doped region 203 in the silicon substrate 200 and the p-type silicon substrate 200 together form a silicon-based photoelectric diode 31, while the second n-type doped region 202 in the silicon germanium epitaxial layer 201 and the p-type silicon substrate 200 together form a silicon germanium-based photoelectric diode 32. A first transistor 34 and a second transistor 35 are also formed on the p-type silicon substrate 200; the first transistor 34 comprises a first n-type source region 204, a gate oxide layer 207, a first gate electrode 208 and an n-type drain region 205; and the second transistor 35 comprises an n-type region 205 and a gate oxide layer 207 which is shared by the first transistor 34, a second gate electrode 210 and a second n-type source region 206 formed in the silicon germanium epitaxial layer 201. A conductive floating node 209 serving as a charge storage node is connected with the n-type drain region 205. Preferably, the material of the floating node 209 is doped polycrystalline silicon, tungsten or titanium nitride.

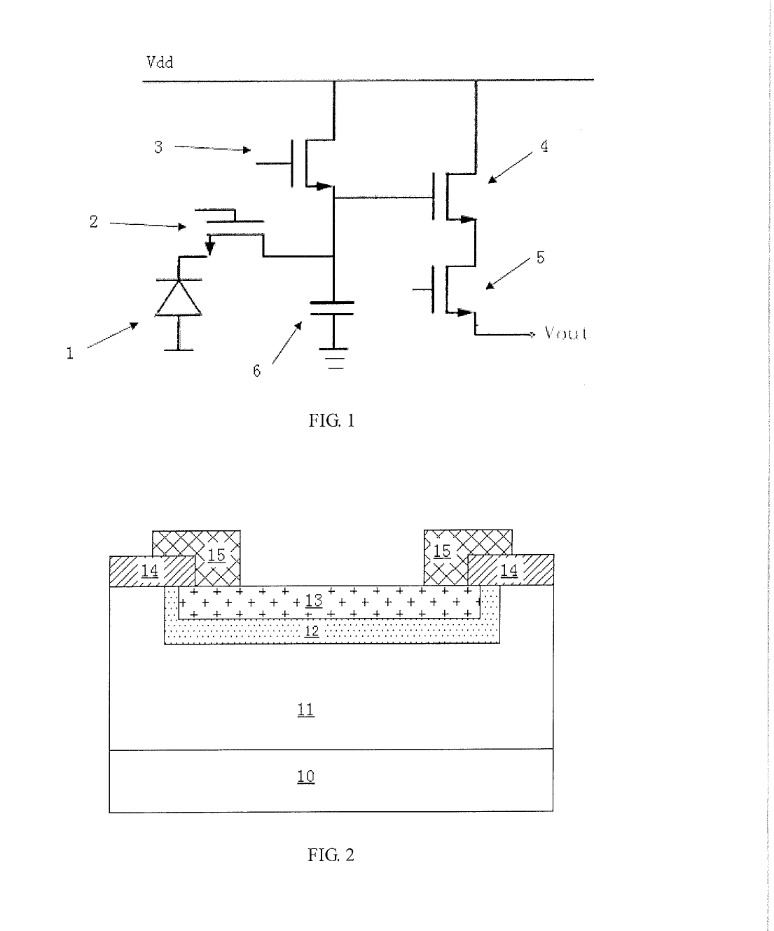

As shown in FIG. 5, the peripheral circuit outside the dotted line 401 is identical with that of the circuit of the single pixel unit of the existing CMOS image sensor as shown in FIG. 1. The circuit in the dotted line 401 is the circuit of the near-infrared-visible light adjustable image sensor disclosed in the disclosure as shown in FIG. 4, wherein 31 represents the silicon-based photoelectric diode; 32 represents the silicon germanium-based photoelectric diode; 34 represents the first transistor; and 35 represents the second transistor. The source region of the first transistor 34 is connected with the cathode (the first n-type doped region 203) of the silicon-based photoelectric diode, and the source region of the second transistor 35 is connected with the cathode (the second n-type doped region 202) of the silicon germanium-based photoelectric diode. The capacitor 33 is a conductive floating node serving as a charge storage node, connected with the drain region of the first transistor 34 and the drain region of the second transistor 35.

Compared with the traditional CMOS image sensor, by adding a transfer transistor the disclosure integrates a silicon-based photoelectric diode and a silicon germanium-based photoelectric diode on the same chip to realize that the silicon-based photoelectric diode and a silicon germanium-based photoelectric diode are controlled by the same readout circuit at different time, thus widening the spectrum response scope of the photoreceptor, realizing high integration and multifunction of the chip and reducing the manufacturing cost of the chip.

The near-infrared-visible light adjustable image sensor disclosed in the disclosure can be manufactured by many methods. The following is an embodiment of a manufacturing method for the near-infrared-visible light adjustable image sensor, as shown in FIG. 4, disclosed in the disclosure.

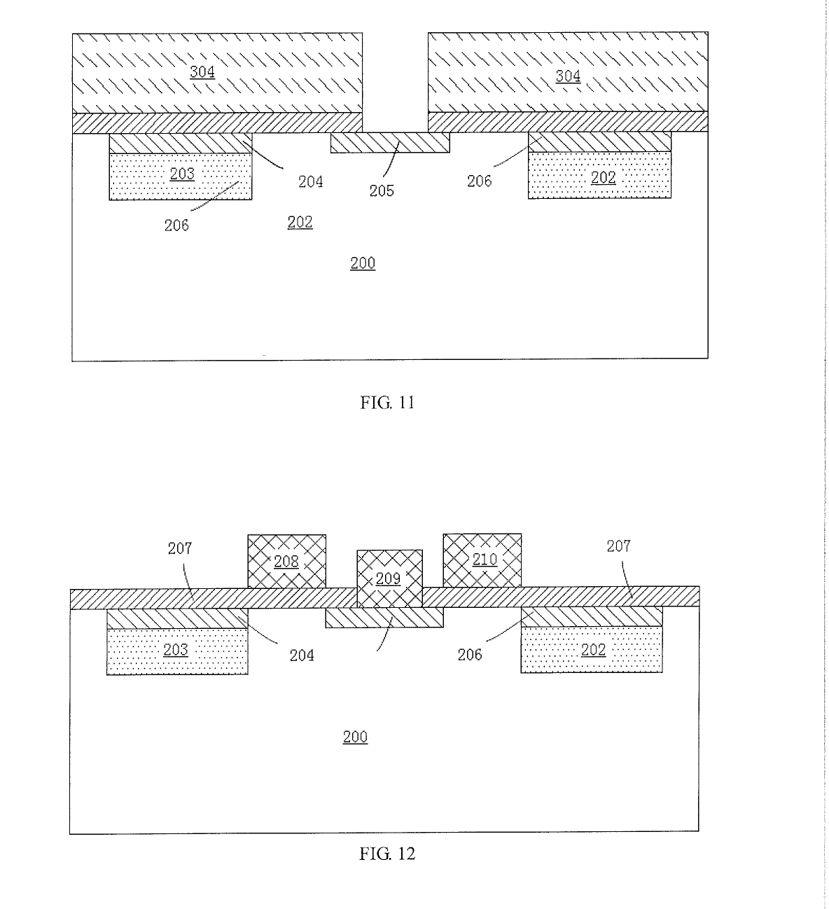

First, as shown in FIG. 6, wash the p-type doped silicon substrate 200 with the well-known RCA's (Radio Corporation of America) washing process, and dry the p-type doped silicon substrate 200 with high-purity nitrogen or in an oven.

Second, spin-coat a photoresist layer 301 on the surface of the processed p-type doped silicon substrate 200, perform masking, exposing and developing to define the position where the epitaxy grows silicon germanium, and etch off the exposed part of the p-type doped silicon substrate 200 to form a region where the epitaxy grows silicon germanium.

Strip the photoresist 301, grow a silicon germanium epitaxial layer 201 in the region formed by etching, and flatten the silicon germanium layer epitaxial layer 201 by using chemical mechanical polishing (CMP) technology, as shown in FIG. 7.

Third, spin-coat a photoresist layer 302 on the formed structure, perform masking, exposing and developing to define the region for subsequent ion injection, then respectively form a first n-type doped region 203 and a second n-type doped region 202 in the p-type silicon substrate 200 and the silicon germanium layer epitaxial layer 201 by ion injection, as shown in FIG. 8;

strip the photoresist layer 302, continuously spin-coat a photoresist layer 303, perform masking, exposing and developing to define the region for subsequent ion injection, then respectively form a first n-type source region 204, an n-type drain region 205 and a second n-type source region 206 which are heavily doped in the first n-type doped region 203, the p-type silicon substrate 200 and the second n-type doped region 202 formed in the silicon germanium layer epitaxial layer, as shown in FIG. 9.

Fourth, strip the photoresist layer 303, and grow a gate oxide layer 207 on the surfaces of the silicon substrate 200 and the silicon germanium layer epitaxial layer 201 by using a low temperature process, wherein the gate oxide layer 207 may be silicon oxide, as shown in FIG. 10.

Fifth, spin-coat a photoresist layer 304 on the oxide layer 207, perform masking, exposing and developing to define the position of the n-type drain region 205, and then etch off the exposed oxide layer 207 to expose the n-type drain region 205, as shown in FIG. 11.

And sixth, strip the photoresist layer 304, deposit a conductive layer on the surface of the formed device, wherein said conductive layer preferably may be doped polycrystalline silicon, tungsten or titanium nitride; and then etch said conductive layer by using the photoetching and etching processes to form the first gate electrode 208 and the second gate electrode 210 of the transistor and the conductive floating node 209 serving as the charge storage node, as shown in FIG. 12.

As mentioned above, many embodiments with huge difference can be made within the spirit and scope of the disclosure. It should be known that except for those limited by the claims, the disclosure is not limited to the embodiment in the description.

1. A near-infrared-visible light adjustable image sensor, comprising:
a p-type doped silicon substrate;
a silicon-based photoelectric diode formed on side silicon substrate;
a silicon germanium-based photoelectric diode formed on side silicon substrate;
a first transistor and a second transistor formed in said silicon substrate and between said silicon-based photoelectric diode and said silicon germanium-based photoelectric diode;
and a conductive floating node formed on said silicon substrate and between said first and second transistors and serving as a charge storage node.

2. The near-infrared-visible light adjustable image sensor according to claim 1, characterized in that the source region of said first transistor is connected with the n-type doped region of said silicon-based photoelectric diode.

3. The near-infrared-visible light adjustable image sensor according to claim 1, characterized in that the source region of said second transistor is connected with the n-type doped region of said silicon germanium-based photoelectric diode.

4. The near-infrared-visible light adjustable image sensor according to claim 1, characterized in that said first and second transistors share the same drain region, and said drain region is connected with said floating node.

5. A manufacturing method for near-infrared-visible light adjustable image sensor according to claim 1, comprising:
etching the provided p-type doped silicon substrate to form a region for forming a silicon germanium-based photoelectric diode;
growing a layer of silicon germanium on the epitaxy in the region for forming said silicon germanium-based photoelectric diode;
respectively forming a first n-type doped region and a second n-type doped region in the said silicon substrate and the epitaxial layer of the formed silicon germanium;
respectively forming a first n-type source region, a second n-type source region and an n-type region which all are heavily doped in said first n-type doped region, said second n-type doped region and said silicon substrate between said first and second n-type doped regions;
forming a gate oxide layer on the surface of the formed structure;
Etching said gate oxide layer to expose said n-type drain region;
forming conductive layers on said gate oxide layer between said first n-type source region and said n-type drain region and on the gate oxide layer between said second n-type source region and said n-type drain region, and forming a conductive floating node serving as a charge storage node on the surface of said exposed n-type region.
